(19) United States
(12) Patent Application Publication
(10) Pub. No.: US 2016/0005999 A1
(43) Pub. Date: Jan. 7, 2016

(54) Adhesive Film for Organic Electronic Device and Encapsulant Comprising the Same

(71) Applicant: INNOX corporation, Chungcheongnam-do (KR)

(72) Inventors: Hwi Yong Lee, Gyeonggi-do (KR); Jin Hyuk Kim, Gyeonggi-do (KR); Chung Gu Lee, Seoul (KR); Bon Su Koo, Gyeongsangbuk-do (KR); Jeong Min Park, Busan (KR)

(21) Appl. No.: 14/552,151

(22) Filed: Nov. 24, 2014

(30) Foreign Application Priority Data
Jul. 1, 2014 (KR) 10-2014-0082067

(51) Int. Cl. H01L 51/52

(52) U.S. Cl. CPC H01L 51/5256; H01L 51/5259

(57) ABSTRACT

Disclosed are an adhesive film for an organic electronic device and an encapsulant including the same, wherein the adhesive film can function to remove or block defect causes such as moisture and impurities so that the defect causes do not approach the organic electronic device, and also to minimize problems due to separation of the organic electronic device and the film and/or interfacial film delamination upon moisture removal.

### CROSS-REFERENCE TO RELATED PATENT APPLICATIONS

This patent application claims priority to Korean Patent Application No. 10-2014-0082067, filed Jul. 1, 2014, the entire teachings and disclosure of which are incorporated herein by reference thereto.

### BACKGROUND OF THE INVENTION

1. Field of the Invention

The present invention relates to an adhesive film for an organic electronic device and an encapsulant including the same, and more particularly, to an adhesive film for an organic electronic device and an encapsulant including the same, wherein the adhesive film is responsible for removing or blocking defect causes such as moisture or impurities so that the defect causes do not approach the organic electronic device, and also for minimizing problems due to separation of the organic electronic device and the film and/or interfacial film delamination upon moisture removal.

2. Description of the Related Art

An organic light emitting diode (OLED) is a light emitting diode configured such that a light emitting layer is composed of an organic compound in thin film form, and employs an electroluminescent phenomenon for generating light by applying current to a fluorescent organic compound. Such OLEDs show main colors in a three-color (Red, Green, Blue) independent pixel mode, a color change medium (CCM) mode or a color filter mode. These OLEDs are classified into small molecule OLEDs and polymer OLEDs, depending on the amount of the organic material contained in a light emitting material, and are also classified into passive OLEDs and active OLEDs depending on the driving mode.

Such OLEDs have high efficiency, low voltage driving and simple operation due to self-emission thereof, and thus enable high-quality mobile images to be displayed. Furthermore, applications thereof into flexible displays and organic electronic devices using flexible properties of organic materials are expected.

An OLED is manufactured in such a manner that an organic compound is stacked in the form of a thin film as a light emitting layer on a substrate. However, since organic compounds used for OLEDs are very sensitive to impurities, oxygen and moisture, the properties thereof may easily deteriorate due to external exposure or moisture/oxygen penetration. Such degradation of the organic materials may affect emission characteristics of the OLEDs and may shorten the lifetime thereof. With the goal of solving these problems, a thin film encapsulation process is required to prevent introduction of oxygen and moisture into organic electronic devices.

Conventionally, Korean Patent Application Publication No. 2006-0030718 discloses an encapsulation method in which a metal can or glass is processed in the form of a cap having a groove and then a powdery dehumidifying agent is placed in such a grove to absorb moisture. However, as this method cannot prevent moisture penetration into encapsulated organic electronic devices, research into overcoming the problems is ongoing.

Methods of preventing moisture from reaching the organic electronic device due to moisture penetration may be divided into blocking moisture and removing moisture. Since it is very difficult to completely block moisture, removal of moisture may be used together with the method of blocking moisture.

In the method of removing penetrated moisture from the encapsulant, incorporation of a moisture removal material into an encapsulant may be taken into consideration. In this case, because of gas or heat generated by removing moisture using the moisture removal material or volume expansion of the moisture removal material due to moisture removal, separation of the organic electronic device and the encapsulant or film thinning may result. Furthermore, interlayer interfacial delamination in a multilayered encapsulant, pore generation, or physical/chemical damage to the organic electronic device may occur. Briefly, the use of such a material may achieve a primary purpose such as moisture removal, but may be accompanied by side effects during or due to moisture removal. Moreover, in order to eliminate such undesired side effects, when the moisture removal material is not contained in a portion of the encapsulant in direct contact with the organic electronic device but is contained in a portion of the encapsulant that does not come into direct contact with the organic electronic device, penetrated moisture cannot be removed as desired and thus may reach the organic electronic device. Hence, there are urgent needs to develop an encapsulant able to prevent side effects such as separation of the encapsulant, film thinning, cracking, and physical/chemical damage to the organic electronic device, which are caused by the moisture removal material and/or by the absorption of moisture into the moisture removal material while ensuring complete moisture removal even when the moisture removal material is contained in a portion of the encapsulant in direct contact with the organic electronic device.

### SUMMARY OF THE INVENTION

Therefore, the present invention has been made keeping in mind the problems encountered in the related art, and the present invention is intended to provide an adhesive film for an organic electronic device and an encapsulant including the same, wherein the adhesive film may function to effectively block or remove defect causes such as moisture, oxygen and impurities to prevent the defect causes from reaching the organic electronic device so as not to generate defects of the organic electronic device, and may also play a role in stopping a variety of problems such as separation of the encapsulant, film thinning, cracking or physical/chemical damage to the organic electronic device in the course of the removal of such defect causes.

Accordingly, the present invention provides an adhesive film for an organic electronic device, comprising: a first adhesive layer including a moisture sorbent and a first adhesive component; and a second adhesive layer formed on the first adhesive layer and including a moisture sorbent and a second adhesive component, wherein the moisture sorbent of the first adhesive layer includes 50 wt % or more of hollow silica.

In a preferred embodiment of the present invention, the first adhesive component and the second adhesive component include any one or more functional groups selected from among thermocurable or photocurable glycidyl, isocyanate, hydroxyl, carboxyl, alkenyl, alkynyl and acrylate groups.

Also, the moisture sorbent of the first adhesive layer may be used in an amount of 10˜50 parts by weight based on the first adhesive component.

Also, the moisture sorbent of the first adhesive layer and the second adhesive layer may satisfy Relation 1 below.

$$1.0 \leq \frac{\begin{matrix}weight ( g ) of moisture \\ sorbent of 2 nd adhesive layer\end{matrix}}{\begin{matrix}weight ( g ) of moisture \\ sorbent of 1 st adhesive layer\end{matrix}} \leq 3.6 \qquad [ Relation 1 ]$$

Also, the hollow silica may have a spherical shape, with an average particle size of 10˜800 nm.

Also, the moisture sorbent of the first adhesive layer may include 80 wt % or more of hollow silica.

Furthermore, the moisture sorbent of the first adhesive layer and the second adhesive layer may satisfy Relation 1 below.

$$1.8 \leq \frac{\begin{matrix}weight ( g ) of moisture \\ sorbent of 2 nd adhesive layer\end{matrix}}{\begin{matrix}weight ( g ) of moisture \\ sorbent of 1 st adhesive layer\end{matrix}} \leq 3.6 \qquad [ Relation 1 ]$$

Also, the second adhesive layer may be provided in the form of a monolayer or a multilayer.

Also, the moisture sorbent of the second adhesive layer may be used in an amount of 20˜100 parts by weight based on 100 parts by weight of the second adhesive component.

Also, the first adhesive layer or the second adhesive layer may have a thickness at least two times the average particle size of the moisture sorbent of each layer.

In addition, the present invention provides an encapsulant for an organic electronic device, comprising the adhesive film as above.

In addition, the present invention provides a light emitting device, comprising a substrate, an organic electronic device formed on at least one side of the substrate, and the encapsulant as above for packaging the organic electronic device.

As used herein, “on layer” means not only direct layer formation on any one layer but also indirect layer formation on any one layer including a further layer intervened between layers. For example, “B layer formed on A layer” means not only that B layer is directly formed on A layer but also that C layer is formed on A layer and then B layer is formed on the C layer.

As used herein, “moisture sorbent” refers to a moisture absorption material, which is converted into a novel material due to absorption of moisture via chemical reaction, as well as a moisture adsorption material, the composition of which is not changed by adsorbing moisture to the interface of the moisture sorbent through physical or chemical bonding such as Van der Waals force.

As used herein, “organic electronic device” refers to an OLED or a device including the same.

According to the present invention, an adhesive film for an organic electronic device is effective at blocking oxygen, impurities and moisture and also at removing penetrated moisture so that the moisture does not reach the organic electronic device. Furthermore, problems upon moisture removal, including volume expansion, gas generation and heat generation to thus cause physical/chemical damage to the organic electronic device, separation of the organic electronic device and the adhesive film, interlayer interfacial delamination of the adhesive film, cracking, and pore generation, can be prevented, thereby remarkably increasing the lifetime and durability of the organic electronic device.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view illustrating an adhesive film for an organic electronic device according to a preferred embodiment of the present invention;

FIG. 2 is a transmission electron microscope (TEM) image illustrating hollow silica of the adhesive film according to a preferred embodiment of the present invention;

FIG. 3 is a schematic cross-sectional view illustrating hollow silica of the first adhesive layer of the adhesive film according to a preferred embodiment of the present invention; and

FIG. 4 is a schematic cross-sectional view illustrating a light emitting device according to a preferred embodiment of the present invention.

### DESCRIPTION OF SPECIFIC EMBODIMENTS

Hereinafter, a detailed description will be given of the present invention.

As mentioned above, because of gas or heat generated by removing moisture using a moisture removal material contained in an encapsulant such as a film for use in encapsulating an organic electronic device or because of volume expansion of the moisture removal material due to the moisture removal, separation of the organic electronic device and the encapsulant, film thinning or cracking may result. Furthermore, interlayer interfacial delamination in a multilayered encapsulant, pore generation, or physical/chemical damage to the organic electronic device may occur. In this case, the use of such a material may achieve a primary purpose such as moisture removal, but may be accompanied by side effects during or due to moisture removal. Moreover, in order to eliminate such undesired side effects, when the moisture removal material is not contained in a portion of the encapsulant in direct contact with the organic electronic device but is contained in a portion of the encapsulant that does not come into direct contact with the organic electronic device, the moisture that reaches the organic electronic device via penetration cannot be removed as desired, making it difficult to increase durability of the organic electronic device.

Accordingly, the present invention addresses an adhesive film for an organic electronic device, comprising: a first adhesive layer including a moisture sorbent and a first adhesive component; and a second adhesive layer formed on the first adhesive layer and including a moisture sorbent and a second adhesive component, wherein the moisture sorbent of the first adhesive layer includes 50 wt % or more of hollow silica. Thereby, oxygen, impurities and moisture may be blocked and also the penetrated moisture may be significantly removed, thus preventing moisture from reaching the organic electronic device and stopping a variety of problems such as separation of the organic electronic device and the encapsulant, film thinning, or cracking in the course of moisture removal. Ultimately, lifetime and durability of the organic electronic device may be remarkably increased.

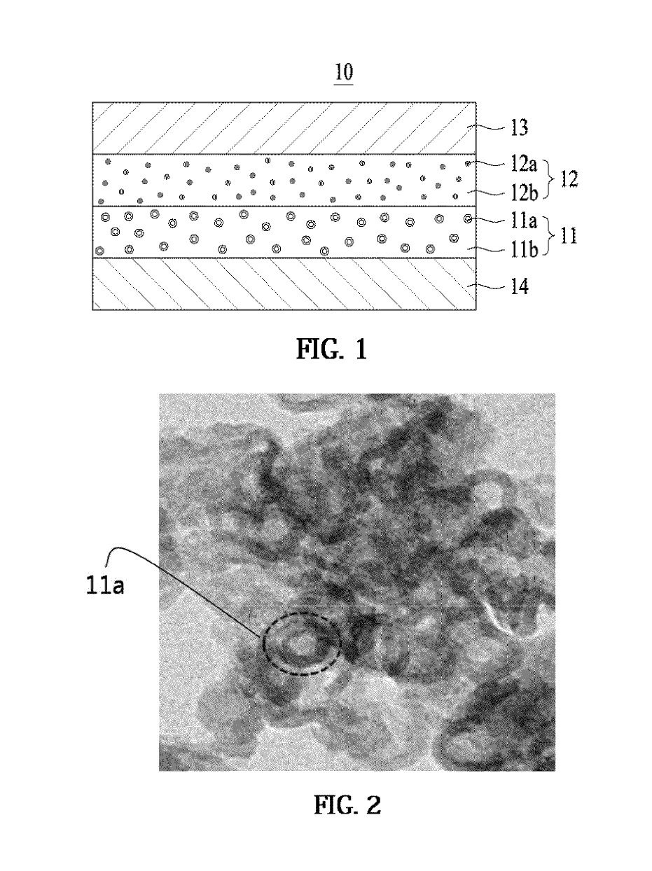

Specifically, FIG. 1 is a cross-sectional view illustrating an adhesive film for an organic electronic device according to a preferred embodiment of the present invention. The adhesive film 10 for an organic electronic device includes a first adhesive layer 11 and a second adhesive layer 12 formed on the first adhesive layer 11, and may further include base films 13, 14 such as a release film on the second adhesive layer 12 and under the first adhesive layer 11 to support and protect the first adhesive layer 11 and the second adhesive layer 12. The first adhesive layer 11 is a layer that comes into direct contact with the organic electronic device (not shown), and includes a moisture sorbent 11a containing hollow silica and a first adhesive component 11b, and the second adhesive layer 12 includes a moisture sorbent 12a and a second adhesive component 12b.

The first adhesive layer 11, which comes into direct contact with an organic light emitting device and includes the moisture sorbent 11a and the first adhesive component 11b, is described below.

The first adhesive layer 11 of the adhesive film according to the present invention includes the moisture sorbent 11a containing hollow silica.

Conventionally, a film for use in packaging an organic electronic device contains a moisture sorbent for removing or blocking penetrated moisture. However, the moisture sorbent in the film for use in packaging an organic electronic device is provided in such a manner that no moisture sorbent or a small amount of moisture sorbent is contained in a layer in direct contact with the organic electronic device, and thus the penetrated moisture cannot be completely removed from the film and may undesirably reach the organic electronic device. Even when the moisture sorbent is contained, it is not uniformly distributed throughout the film but may agglomerate, making it impossible to remove moisture penetrated into the portion containing no moisture sorbent. On the other hand, when the moisture sorbent is contained in a large amount in the film or is contained in the portion in contact with the organic electronic device to increase moisture removal efficiency, desired moisture removal may be accomplished but direct/indirect damage to the organic electronic device due to the moisture sorbent cannot be prevented. Hence, in order to compromise the conflicting effects of moisture removal efficiency and prevention of damage due to the moisture sorbent, conventional methods are performed in such a manner that the moisture sorbent is not contained in the portion in direct contact with the organic light emitting device and thereby damage to the organic electronic device due to the moisture sorbent may be prevented even though the moisture removal efficiency is decreased attributed to moisture penetration. However, such a film for packaging an organic electronic device cannot increase the durability because of a decrease in the moisture removal efficiency of the organic electronic device, and frequent replacement of the organic electronic device due to the short usage cycle or defects thereof may be incurred. Therefore, the present inventors have carried out studies to solve such problems and thus have found that when specific moisture sorbent, especially hollow silica able to remove moisture by adsorption instead of the moisture absorption is used, no volume expansion may occur by moisture adsorption, and the moisture is not chemically absorbed and thus neither heat nor byproducts are generated. Hence, even when such hollow silica is contained in the layer in direct contact with the organic electronic device, separation of the organic electronic device and the adhesive film, cracking and pore generation do not occur, and also, direct/indirect damage to the organic electronic device is not caused, thus considerably increasing durability of the organic electronic device, which culminates in the present invention.

The moisture sorbent 11a of the first adhesive layer has to possess hollow silica in an amount of 50 wt % or more, preferably 70 wt % or more, more preferably 80 wt % or more, much more preferably 90 wt % or more, and still more preferably 95 wt % or more. If the amount of hollow silica of the moisture sorbent in the first adhesive layer is less than 50 wt %, desired moisture removal performance cannot be ensured. Furthermore, the moisture removal performance may be obtained, but volume expansion of the moisture sorbent, heat or byproducts may be generated by the moisture removal, undesirably incurring separation of the organic electronic device and the encapsulant, film thinning or cracking and also remarkably lowering durability of the organic electronic device attributed to physical/chemical damage thereto.

The moisture sorbent 11a may further include, in addition to hollow silica, another kind of moisture sorbent. The other kind of moisture sorbent is not limited so long as it is typically contained in a film for packaging an organic electronic device, but the moisture sorbent preferably includes a moisture adsorption material that has no physical volume expansion via reaction with moisture and causes neither chemical composition conversion nor heat generation. Non-limiting examples of the moisture adsorption material may include zeolite, titania, zirconia, and Montmorillonite, which may be used alone or in combination of two or more. The other kind of moisture sorbent is not limited in shape and diameter, and may have the same or different shape and diameter as or from the hollow silica that will be described later. As such, a spherical shape is preferable in terms of dispersibility.

The moisture sorbent 11a may have a purity of 95% or more. If its purity is less than 95%, moisture sorption performance may deteriorate, and the material contained in the moisture sorbent may act as an impurity, thus causing defects in the adhesive film and deteriorating durability of the organic electronic device. Hence, the use of a moisture sorbent having a purity of 95% or more is preferable.

In a preferred embodiment of the present invention, as for the first adhesive layer, the moisture sorbent 11a containing hollow silica may be used in an amount of 10˜50 parts by weight based on the first adhesive component. If the amount of the moisture sorbent 11a is less than 10 parts by weight, moisture removal effects cannot be achieved in the first adhesive layer, undesirably deteriorating durability of the organic electronic device. In contrast, if the amount of the moisture sorbent exceeds 50 parts by weight, wettability may decrease and thus lamination such as close contact or adhesion between the adhesive film and the organic electronic device may become poor, undesirably lowering reliability of the organic electronic device.

Below is a description of the hollow silica.

Hollow silica functions to effectively remove penetrated moisture by incorporating moisture into the hollow portion thereof, and thus heat or gas is not generated due to the adsorption of moisture. The volume of hollow silica is not expanded after the adsorption of moisture. Even when hollow silica is contained in a large amount in the layer in direct contact with the organic electronic device, physical/chemical damage to the organic electronic device may be prevented.

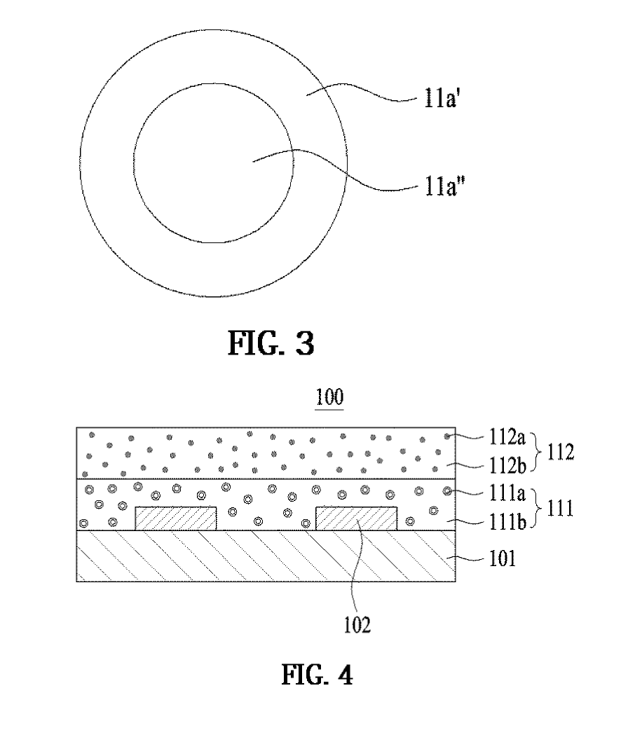

Specifically, FIG. 2 is a TEM image illustrating hollow silica in the first adhesive layer of the adhesive film according to a preferred embodiment of the present invention, FIG. 3 is a schematic cross-sectional view illustrating the hollow silica of FIG. 2 wherein the hollow silica 11a includes a shell portion 11a′ and a hollow portion 11a″ empty in the shell portion 11a′.

The average particle size of the hollow silica 11a may be 10˜800 nm. As such, the particle size refers to a diameter when the hollow silica has a spherical shape, and to a maximum distance among linear distances ranging from any one point to the other point on the surface of the hollow silica when the shape of the hollow silica is not spherical.

The hollow silica 11a preferably has a diameter of 10˜800 nm, and more preferably 10˜700 nm. If the diameter thereof is less than 10 nm, the capacity thereof able to incorporate moisture may decrease, undesirably deteriorating moisture adsorption performance. In this case, removal of moisture requires a large amount of the moisture sorbent, which is undesirable. In contrast, if the diameter thereof exceeds 800 nm, the organic electronic device may be directly physically damaged due to the moisture sorbent, undesirably creating dark spots.

The hollow portion 11a″ of the hollow silica 11a is a space in which the moisture adsorbed through the shell portion 11a′ is incorporated, and the diameter of the hollow portion is preferably 5˜785 nm. If the diameter thereof is less than 5 nm, the amount of incorporated moisture may decrease, undesirably deteriorating moisture removal effects. In contrast, if the diameter thereof is greater than 285 nm, the particle size of the hollow silica may exceed the given range or the thickness of the shell portion 11a′ may decrease, undesirably breaking the shell portion 11a′, and thus the hollow silica cannot exhibit moisture sorption performance.

The hollow silica 11a may have a spherical shape. According to the present invention, the hollow silica 11a of the first adhesive layer 11 should be uniformly dispersed in the first adhesive component that will be described later. When the hollow silica 11a has a spherical shape rather than a needle shape or a polyhedral shape, dispersibility may become good, thereby obtaining an adhesive film having desired properties.

Meanwhile, in order to increase penetrated moisture sorption efficiency, the moisture sorbent should be uniformly dispersed throughout the first adhesive layer. However, the moisture sorbent, particles of which may easily agglomerate, is difficult to uniformly disperse in the first adhesive layer. If the moisture sorbent is not uniformly dispersed, moisture that penetrates the region having no moisture sorbent cannot be sorbed and thus durability of the organic electronic device may deteriorate. According to the present invention, the moisture sorbent of the first adhesive layer preferably includes hollow silica 11a having an average particle size of 10˜800 nm to solve problems due to non-uniform dispersion. The dispersion coefficient for the particle size of the hollow silica relative to a predetermined average particle size is preferably 30% or more, more preferably 30˜70%, based on Relation 2 below.

$$Coefficient of Variation ( CV , \% ) = \frac{ SD ( μ m ) of particle size of hollow silica}{ average particle size ( μ m ) of hollow silica} \times 100 \qquad [ Relation 2 ]$$

In this relation, SD represents the standard deviation.

The dispersion coefficient indicates the extent that the measurement value is dispersed relative to the average value, and thereby the degree of dispersion of the hollow silica particles relative to the average particle size may be determined. As the numeral value thereof is lower, a uniform particle size close to the average particle size may be obtained.

According to the present invention, when hollow silica satisfies a dispersion coefficient of 30% or more for a particle size, it may be composed of particles having various particle sizes. Thereby, as the dispersibility increases, such hollow silica may be uniformly distributed in the first adhesive layer in direct contact with the organic electronic device, thus preventing damage to the organic electronic device. However, in the case where the dispersion coefficient exceeds 70%, the moisture sorbent including hollow silica having a large particle size may be contained in the first adhesive layer, undesirably damaging the organic electronic device.

Next, the first adhesive component 11b, which is contained together with the moisture sorbent 11a including hollow silica in the first adhesive layer 11, is described below.

The first adhesive component 11b may be used without limitation so long as it is typically useful in packaging an organic electronic device. Preferably useful is an adhesive component, which may be easily adhered to an organic electronic device, is not peeled due to superior adhesion, does not physically chemically affect the organic electronic device and is compatible with the hollow silica. The first adhesive component 11b may be a curable adhesive component, including thermocurable, photocurable or hybrid curable adhesive components as known in the art. The thermocurable adhesive component enables curing to occur through appropriate application of heat or an aging process, and the photocurable adhesive component enables curing to proceed by irradiation of light (active energy rays). Also, the hybrid curable adhesive component enables curing to progress by simultaneously or sequentially carrying out the curing mechanisms of thermocurable and photocurable adhesive components. Furthermore, examples of light applied to the photocurable adhesive component may include microwaves, IR, UV, X-rays and γ-rays, and particle beams such as α-particle beams, proton beams, neutron beams and electron beams.

The curable adhesive component, which may exhibit adhesion by curing, may include at least one thermocurable functional group or moiety selected from among a glycidyl group, an isocyanate group, a hydroxyl group, a carboxyl group and an amide group, or at least one photocurable functional group or moiety selected from among an epoxide group, a cyclic ether group, a sulfide group, an acetal group and a lactone group. The curable adhesive component may be exemplified by, but is not limited to, an acryl component, a polyester component, an isocyanate component or an epoxy component, having at least one functional group or moiety as above. Particularly useful is an epoxy component in order to reduce moisture penetration while exhibiting superior adhesion upon curing. Examples of the epoxy component may include glycidylether-, glycidylamine-, glycidylester-based epoxy components, linear aliphatic epoxy component, cyclo-aliphatic epoxy component, heterocyclic epoxy component, substituted epoxy component, naphthalene-based epoxy component and derivatives thereof, and bifunctional or polyfunctional components, which may be used alone or in combination.

More specifically, the glycidylether-based epoxy component includes phenolic glycidylether and alcoholic glycidylether. Examples of the phenolic glycidylether may include bisphenol-based epoxy such as bisphenol A, bisphenol B, bisphenol AD, bisphenol S, bisphenol F and resorcinol; phenol-based novolac such as phenol novolac epoxy, aralkylphenol novolac or terpen-phenol novolac; and cresol novolac epoxy such as o-cresol novolac epoxy, which may be used alone or in combination of two or more. A primary epoxy component is preferably a bisphenol-based epoxy component, and more preferably a bisphenol F epoxy component. As such, superior properties in terms of bump bonding reliability may be obtained compared to the other epoxy components.

Examples of the glycidylamine-based epoxy component may include diglycidylaniline, tetraglycidyldiaminodiphenylmethane, N,N,N′,N′-tetraglycidyl-m-xylenediamine, 1,3-bis(diglycidylaminomethyl)cyclohexane, and triglycidyl-m-aminophenol or triglycidyl-p-aminophenol having both structures of glycidylether and glycidylamine, which may be used alone or in combination of two or more.

Examples of the glycidylester-based epoxy component may include hydroxycarbonic acid such as p-hydroxybenzoic acid or β-hydroxynaphthoic acid, and polycarbonic acid such as phthalic acid or terephthalic acid, which may be used alone or in combination of two or more. Examples of the linear aliphatic epoxy component may include glycidyl ethers, such as 1,4-butanediol, 1,6-hexanediol, neopentylglycol, cyclohexanedimethanol, glycerin, trimethylolethane, trimethylolpropane, pentaerythritol, dodecahydro bisphenol A, dodecahydro bisphenol F, ethyleneglycol, propyleneglycol, polyethyleneglycol, and polypropyleneglycol, which may be used alone or in combination of two or more.

The cyclo-aliphatic epoxy component may be exemplified by 3,4-epoxycyclohexylmethyl-3′,4′-epoxycyclohexanecarboxylate.

Examples of the naphthalene-based epoxy component may include epoxies having a naphthalene backbone, such as 1,2-diglycidylnaphthalene, 1,5-diglycidylnaphthalene, 1,6-diglycidylnaphthalene, 1,7-diglycidylnaphthalene, 2,7-diglycidylnaphthalene, triglycidylnaphthalene, and 1,2,5,6-tetraglycidylnaphthalene, which may be used alone or in combination of two or more.

In addition thereto, triglycidylisocyanurate, or an epoxy component having an epoxycyclohexane ring therein obtained by oxidizing a compound having a plurality of double bonds therein may be used.

The kind and the mixing ratio of such an epoxy component may vary depending on the purposes, and may not be particularly limited in the present invention. The epoxy component may include silicone modified liquid epoxy and DCPD type solid epoxy in order for a cured product to exhibit superior heat resistance, chemical resistance and moisture sorption resistance and to manifest high adhesion to an organic electronic device so as to achieve desired properties. Furthermore, the epoxy component may be a high-purity epoxy component having a total Cl content of 500 ppm or less. If the Cl content exceeds 500 ppm, Cl may act as an impurity and may thus negatively affect the organic electronic device, undesirably deteriorating durability of the device. When two or more adhesive components are added, the total Cl content is preferably 500 ppm or less in each of the adhesive components. More preferably, the total Cl content is 500 ppm or less in the entire adhesive component.

According to the present invention, the first adhesive component 11b of the first adhesive layer 11 may further include a film forming component. The film forming component plays a role in increasing film formability that refers to mechanical properties for preventing the film from being easily torn, broken or becoming sticky. When the film is easily handled under typical conditions (e.g. room temperature), film formability is regarded as good. Such a film forming component may be used without limitation.

Non-limiting examples of the film forming component may include polyester, polyether, polyamide, polyamideimide, polyimide, polyvinylbutyral, polyvinylformal, phenoxy, polyhydroxypolyether, acryl, polystyrene, butadiene, acrylonitrilebutadiene copolymer, acrylonitrilebutadiene styrene, styrenebutadiene copolymer and acrylic components, which may be used alone or in combination of two or more.

The film forming component may be a polymer having an epoxy group, and specifically a polymer having an epoxy group at a terminal and/or a side chain (a pendent position). Non-limiting examples thereof may include epoxy group-containing acryl rubber, epoxy group-containing butadiene rubber, bisphenol type high-molecular-weight epoxy component, epoxy group-containing phenoxy component, epoxy group-containing acryl component, epoxy group-containing urethane component, and epoxy group-containing polyester component, which may be used alone or in combination of two or more. Among the non-limiting examples as listed above, preferably useful is a phenoxy component, which has low ionic impurities able to damage the organic electronic device due to corrosion, possesses high heat resistance and may ensure reliability of the organic electronic device.

The film forming component may be contained in an amount of 100˜300 parts by weight based on 100 parts by weight of the curable adhesive component. If the amount thereof is less than 100 parts by weight, film formability may deteriorate. In contrast, if the amount thereof exceeds 300 parts by weight, fluidity may decrease, undesirably reducing bondability to the organic electronic device.

The first adhesive layer may further include a curing agent or a curing accelerant to cure the first adhesive component 11b as above. The curing agent may be contained in an amount of 0.5˜20 parts by weight based on 100 parts by weight of the first adhesive component, and the curing accelerant may be contained in an amount of 1˜20 parts by weight based on 100 parts by weight of the first adhesive component. However, the amount of the curing agent or the curing accelerant may vary depending on the kind and the proportion of the functional group of the curable adhesive component or depending on desired crosslinking density.

The kind of curing agent may be appropriately selected and used depending on the kind of functional group contained in the curable adhesive component, and any curing agent known in the art may be employed. When the curable adhesive component is an epoxy component, non-limiting examples of the usable curing agent may include aliphatic amines such as diethylenetriamine or triethylenetetramine; aromatic amines such as m-phenylenediamine, diaminodiphenylmethane, diaminodiphenylsulfone, or azomethylphenol; polyhydric hydroxyl compounds such as phenol novolac resin, o-cresol novolac resin, naphthol novolac resin, or phenol aralkyl resin, and modified products thereof; acid anhydride-based curing agents such as phthalic anhydride, maleic anhydride, hexahydrophthalic anhydride, or pyromellitic anhydride; latent curing agents such as dicyandiamide, imidazole, BF3-amine complex, guanidine derivatives, which may be used alone or in combination of two or more.

The curing accelerant plays a role in adjusting the curing rate or the properties of cured products, and may be used without limitation so long as it is typically useful for a film for packaging an organic electronic device. Non-limiting examples of the curing accelerant may include imidazole-, and tertiary amine-based curing accelerants. Particularly useful is an imidazole-based curing accelerant because it facilitates the control of a reaction system for adjusting the curing rate or the properties of cured products. These curing accelerants may be used alone or in combination of two or more.

The imidazole-based curing accelerant is not particularly limited, but may be exemplified by 1-cyanoethyl-2-phenylimidazole in which Position 1 of imidazole is protected with a cyanoethyl group, or ^{└}2MA-OK_{┘} in which its basicity is protected by isocyanuric acid (available from Shikoku Kasei Kogyo). These curing accelerants may be used alone or in combination of two or more.

When the acid anhydride-based curing agent and the imidazole-based curing accelerant are used together, the acid anhydride-based curing agent is preferably added in an amount equal to or less than the theoretical equivalent relative to the epoxy group. If the amount of the acid anhydride-based curing agent is excessive, there is a concern about which chloride ions may be easily dissolved by moisture from the cured product having the composition according to the present invention. For example, when the dissolution component is extracted by hot water from the cured product having the composition according to the present invention, the pH of the extracted water may be lowered to about 4˜5, and also chloride ions released from the epoxy resin may be dissolved in a large amount.

Also, when the amine-based curing agent and the imidazole-based curing accelerant are used together, the amine-based curing agent is preferably added in an amount equal to or less than the theoretical equivalent relative to the epoxy group. If the amount of the amine-based curing agent is excessive, chloride ions may be unfavorably easily dissolved by moisture from the cured product having the composition according to the present invention. For example, when the dissolution component is extracted from the cured product by hot water, the extracted water has a basic pH, and also the chloride ions released from the epoxy resin may be dissolved in a large amount, thus damaging the organic electronic device.

In a preferred embodiment of the present invention, the first adhesive layer has a thickness at least two times the average particle size of the moisture sorbent 11a including hollow silica. If the thickness thereof is less than two times the average particle size of the moisture sorbent, the moisture sorbent may protrude from the surface of the first adhesive layer, thus decreasing adhesion to the second adhesive layer formed on the first adhesive layer or adhesion of the first adhesive layer to the substrate in direct contact therewith. Furthermore, a probability of physically damaging the organic electronic device may unfavorably increase.

Next, the second adhesive layer 12, which is formed on the first adhesive layer 11 and includes a moisture sorbent 12a and a second adhesive component 12b, is described below.

The moisture sorbent 12a is specified below.

The moisture sorbent 12a may be a typical moisture sorbent contained in an encapsulant for packaging an organic electronic device, and the kind thereof is not limited. Accordingly, a moisture sorbent including silica including hollow silica, zeolite, titania, zirconia or Montmorillonite, a metal salt, and a metal oxide may be used alone or in combination of two or more.

Non-limiting examples of the metal oxide may include metal oxides such as lithium oxide (Li₂O), sodium oxide (Na₂O), barium oxide (BaO), calcium oxide (CaO) and magnesium oxide (MgO), organometallic oxides and phosphorus pentoxide (P₂O₅), which may be used alone or in combination of two or more.

Non-limiting examples of the metal salt may include, but are not limited to, sulfates such as lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂) or nickel sulfate (NiSO₄); metal halides such as calcium chloride (CaCl₂), magnesium chloride (MgCl₂), strontium chloride (SrCl₂), yttrium chloride (YCl₃), copper chloride (CuCl₂), cesium fluoride (CsF), tantalum fluoride (TaF₅), niobium fluoride (NbF₅), lithium bromide (LiBr), calcium bromide (CaBr₂), cesium bromide (CeBr₃), selenium bromide (SeBr₄), vanadium bromide (VBr₃), magnesium bromide (MgBr₂), barium iodide (BaI₂) or magnesium iodide (MgI₂); and metal chlorates such as barium perchlorate (Ba(ClO₄)₂) or magnesium perchlorate (Mg(ClO₄)₂), which may be used alone or in combination of two or more. The moisture sorbent 12a may have a purity of 95% or more. If the purity thereof is less than 95%, moisture sorption performance may deteriorate, and the material contained in the moisture sorbent may act as an impurity, and thus a poor adhesive film may result and the organic electronic device may be negatively affected. Hence, the use of a moisture sorbent having a purity of 95% or more is preferable.

The moisture sorbent of the second adhesive layer may be used in an amount of 20˜100 parts by weight based on 100 parts by weight of the second adhesive component. If the amount of the moisture sorbent is less than 20 parts by weight based on the second adhesive component, moisture removal effects may be significantly decreased, making it impossible to obtain a desired adhesive film. In contrast, if the amount of the moisture sorbent exceeds 100 parts by weight, adhesion performance of the second adhesive layer may be remarkably decreased. Furthermore, because of excessive volume expansion upon moisture sorption, the first adhesive layer and the second adhesive layer and/or the adhesive layer including the second adhesive layer and the first adhesive layer may become loose from the organic electronic device, and thus moisture may rapidly penetrate the space therebetween, undesirably shortening the lifetime of the organic electronic device.

Meanwhile, the shape or particle size of the moisture sorbent 12a of the second adhesive layer 12 according to the present invention is not limited, but its shape is preferably spherical in order to enhance dispersibility in the second adhesive layer. The average particle size thereof may be 10 nm˜6 μm, and thereby the adhesive film may be provided in the form of a thin film while possessing desired moisture removal performance.

The moisture sorbent 12a of the second adhesive layer may be the same as or different from the moisture sorbent of the first adhesive layer.

Next, the second adhesive component 12b, which is contained together with the moisture sorbent 12a as above in the second adhesive layer 12, is described below.

The second adhesive component 12b may be used without limitation so long as it is typically employed in packaging an organic electronic device. Preferably useful is an adhesive component, which is easily adhered to an organic electronic device, is not peeled due to superior adhesion, does not physically chemically affect the organic electronic device and is compatible with the hollow silica. The second adhesive component 12b may be a curable adhesive component, including thermocurable, photocurable or hybrid curable adhesive components as known in the art. The thermocurable adhesive component enables curing to occur through appropriate application of heat or an aging process, and the photocurable adhesive component enables curing to proceed by irradiation of light (active energy rays). Also, the hybrid curable adhesive component enables curing to progress by simultaneously or sequentially carrying out the curing mechanisms of the thermocurable and photocurable adhesive components. Furthermore, examples of light applied to the photocurable adhesive component may include microwaves, IR, UV, X-rays and γ-rays, and particle beams such as α-particle beams, proton beams, neutron beams and electron beams.

The curable adhesive component may be, for example, a component that is cured and thus exhibits adhesion, and may include at least one thermocurable functional group or moiety selected from among a glycidyl group, an isocyanate group, a hydroxyl group, a carboxyl group and an amide group, or may include at least one photocurable functional group or moiety selected from among an epoxide group, a cyclic ether group, a sulfide group, an acetal group and a lactone group. Examples of the curable adhesive component may include, but are not limited to, an acryl component, a polyester component, an isocyanate component and an epoxy component, having at least one functional group or moiety as above. Preferably useful is an epoxy component in order to decrease moisture penetration while exhibiting superior adhesion upon curing.

More specifically, the glycidylether-based epoxy component includes phenolic glycidylether and alcoholic glycidylether. Examples of the phenolic glycidylether may include bisphenol-based epoxy such as bisphenol A, bisphenol B, bisphenol AD, bisphenol S, bisphenol F and resorcinol; phenol-based novolac such as phenol novolac epoxy, aralkylphenol novolac or terpen-phenol novolac; and cresol novolac epoxy such as o-cresol novolac epoxy, which may be used alone or in combination of two or more. A primary epoxy component is preferably a bisphenol-based epoxy component, and more preferably a bisphenol F epoxy component. As such, superior properties in terms of bump bonding reliability may be obtained compared to the other epoxy components.

Examples of the glycidylamine-based epoxy component may include diglycidylaniline, tetraglycidyl diaminodiphenylmethane, N,N,N′,N′-tetraglycidyl-m-xylenediamine, 1,3-bis(diglycidylaminomethyl)cyclohexane, and triglycidyl-m-aminophenol or triglycidyl-p-aminophenol having both structures of glycidylether and glycidylamine, which may be used alone or in combination of two or more.

Examples of the glycidylester-based epoxy component may include hydroxycarbonic acid such as p-hydroxybenzoic acid or β-hydroxynaphthoic acid and polycarbonic acid such as phthalic acid or terephthalic acid, which may be used alone or in combination of two or more. Examples of the linear aliphatic epoxy component may include glycidyl ethers, such as 1,4-butanediol, 1,6-hexanediol, neopentylglycol, cyclohexanedimethanol, glycerin, trimethylolethane, trimethylolpropane, pentaerythritol, dodecahydro bisphenol A, dodecahydro bisphenol F, ethyleneglycol, propyleneglycol, polyethyleneglycol, and polypropyleneglycol, which may be used alone or in combination of two or more.

The cyclo-aliphatic epoxy component may be exemplified by 3,4-epoxycyclohexylmethyl-3′,4′-epoxycyclohexanecarboxylate.

Examples of the naphthalene-based epoxy component may include epoxies having a naphthalene backbone, such as 1,2-diglycidylnaphthalene, 1,5-diglycidylnaphthalene, 1,6-diglycidylnaphthalene, 1,7-diglycidylnaphthalene, 2,7-diglycidylnaphthalene, triglycidylnaphthalene, and 1,2,5,6-tetraglycidylnaphthalene, which may be used alone or in combination of two or more.

In addition thereto, triglycidylisocyanurate, or an epoxy component having an epoxycyclohexane ring therein obtained by oxidizing a compound having a plurality of double bonds therein may be used.

The kind and the mixing ratio of such an epoxy component may vary depending on the purposes, and may not be particularly limited in the present invention. The epoxy component may include silicone modified liquid epoxy and DCPD type solid epoxy in order for a cured product to exhibit superior heat resistance, chemical resistance and moisture sorption resistance and to manifest high adhesion to an organic electronic device so as to achieve desired properties. Furthermore, the epoxy component may be a high-purity epoxy component having a total Cl content of 500 ppm or less. If the Cl content exceeds 500 ppm, Cl may act as an impurity and may thus negatively affect the organic electronic device, undesirably deteriorating durability of the device. When two or more adhesive components are added, the total Cl content is preferably 500 ppm or less in each of the adhesive components. More preferably, the total Cl content is 500 ppm or less in the entire adhesive component.

According to the present invention, the second adhesive component 12b of the second adhesive layer 12 may further include a film forming component. The film forming component plays a role in increasing film formability that refers to mechanical properties for preventing the film from being easily torn, broken or becoming sticky. When the film is easily handled under typical conditions (e.g. room temperature), film formability is regarded as good. Such a film forming component may be used without limitation.

Non-limiting examples of the film forming component may include polyester, polyether, polyamide, polyamideimide, polyimide, polyvinylbutyral, polyvinylformal, phenoxy, polyhydroxypolyether, acryl, polystyrene, butadiene, acrylonitrilebutadiene copolymer, acrylonitrilebutadiene styrene, styrenebutadiene copolymer, and acrylic components, which may be used alone or in combination of two or more.

The film forming component may be a polymer having an epoxy group, and specifically a polymer having an epoxy group at a terminal and/or a side chain (a pendent position). Non-limiting examples thereof may include epoxy group-containing acryl rubber, epoxy group-containing butadiene rubber, bisphenol type high-molecular-weight epoxy component, epoxy group-containing phenoxy component, epoxy group-containing acryl component, epoxy group-containing urethane component, and epoxy group-containing polyester component, which may be used alone or in combination of two or more. Among the non-limiting examples as listed above, preferably useful is a phenoxy component, which has low ionic impurities able to damage the organic electronic device due to corrosion, possesses high heat resistance and may ensure reliability of the organic electronic device.

The film forming component may be used in an amount of 100˜300 parts by weight based on 100 parts by weight of the curable adhesive component contained in the second adhesive layer. If the amount thereof is less than 100 parts by weight, film formability may deteriorate. In contrast, if the amount thereof exceeds 300 parts by weight, fluidity may decrease, undesirably deteriorating bondability to the organic electronic device.

The second adhesive layer 12 may further include a curing agent or a curing accelerant to cure the second adhesive component 12b as above. The curing agent may be contained in an amount of 0.5˜20 parts by weight based on 100 parts by weight of the second adhesive component, and the curing accelerant may be contained in an amount of 1˜20 parts by weight based on 100 parts by weight of the second adhesive component. However, the amount of the curing agent or the curing accelerant may vary depending on the kind and the proportion of the functional group of the curable adhesive component or depending on the desired crosslinking density.

The kind of curing agent may be appropriately selected and used depending on the kind of functional group contained in the curable adhesive component, and any curing agent known in the art may be employed. When the curable adhesive component is an epoxy component, non-limiting examples of the usable curing agent may include aliphatic amines such as diethylenetriamine or triethylenetetramine; aromatic amines such as m-phenylenediamine, diaminodiphenylmethane, diaminodiphenylsulfone, or azomethylphenol; polyhydric hydroxyl compounds such as phenol novolac resin, o-cresol novolac resin, naphthol novolac resin, or phenol aralkyl resin, and modified products thereof; acid anhydride-based curing agents such as phthalic anhydride, maleic anhydride, hexahydrophthalic anhydride, or pyromellitic anhydride; latent curing agents such as dicyandiamide, imidazole, BF3-amine complex, guanidine derivatives, which may be used alone or in combination of two or more.

The curing accelerant plays a role in adjusting the curing rate or the properties of cured products, and may be used without limitation so long as it is typically useful for a film for packaging an organic electronic device. Non-limiting examples of the curing accelerant may include imidazole-, and tertiary amine-based curing accelerants. Particularly useful is an imidazole-based curing accelerant because it facilitates the control of a reaction system for adjusting the curing rate or the properties of cured products. These curing accelerants may be used alone or in combination of two or more.

The imidazole-based curing accelerant is not particularly limited, but may be exemplified by 1-cyanoethyl-2-phenylimidazole in which Position 1 of imidazole is protected with a cyanoethyl group, or ^{└}2MA-OK_{┘} in which its basicity is protected by isocyanuric acid (available from Shikoku Kasei Kogyo). These curing accelerants may be used alone or in combination of two or more.

When the acid anhydride-based curing agent and the imidazole-based curing accelerant are used together, the acid anhydride-based curing agent is preferably added in an amount equal to or less than the theoretical equivalent relative to the epoxy group. If the amount of the acid anhydride-based curing agent is excessive, chloride ions may be unfavorably easily dissolved by moisture from the cured product having the composition according to the present invention. For example, when the dissolution component is extracted by hot water from the cured product having the composition according to the present invention, the pH of the extracted water may be lowered to about 4˜5, and also chloride ions released from the epoxy resin may be dissolved in a large amount.

Also, when the amine-based curing agent and the imidazole-based curing accelerant are used together, the amine-based curing agent is preferably added in an amount equal to or less than the theoretical equivalent relative to the epoxy group. If the amount of the amine-based curing agent is excessive, there is a worry about which chloride ions may be easily dissolved by moisture from the cured product having the composition according to the present invention. For instance, when the dissolution component is extracted from the cured product by hot water, the extracted water has a basic pH, and also chloride ions released from the epoxy resin may be dissolved in a large amount, thus damaging the organic electronic device.

Meanwhile, in the present invention, the adhesive layer including the first adhesive component except for the moisture sorbent of the first adhesive layer may have the same or different composition as or from the adhesive layer including the second adhesive component except for the moisture sorbent of the second adhesive layer.

Meanwhile, in a preferred embodiment of the present invention, the second adhesive layer has a thickness at least two times the average particle size of the moisture sorbent 12a. If the thickness of the second adhesive layer is less than two times the average particle size of the moisture sorbent, the moisture sorbent of the second adhesive layer may protrude from the surface of the second adhesive layer 12, thus decreasing adhesion to the first adhesive layer 11. Hence, interfacial delamination between the adhesive layers may occur, and moisture may rapidly penetrate a space therebetween, significantly deteriorating durability of the organic electronic device. Furthermore, the moisture sorbent 12a may physically invade the first adhesive layer 11, unfavorably damaging the organic electronic device.

In a preferred embodiment of the present invention, the second adhesive layer may be provided in the form of a monolayer or a multilayer, and may be formed on the first adhesive layer in direct contact with the organic light emitting device, and thus does not come into direct contact with the organic light emitting device. Even when the second adhesive layer is multilayered, the above configuration is possible.

The moisture sorbent of the first and the second adhesive layer in the adhesive film according to the present invention may satisfy Relation 1 below.

$$1.0 \leq \frac{\begin{matrix}weight ( g ) of moisture \\ sorbent of 2 nd adhesive layer\end{matrix}}{\begin{matrix}weight ( g ) of moisture \\ sorbent of 1 st adhesive layer\end{matrix}} \leq 3.6 \qquad [ Relation 1 ]$$

When the ratio of the weight of the moisture sorbent of the second adhesive layer relative to the weight of the moisture sorbent of the first adhesive layer falls in the range of Relation 1, moisture that may penetrate the adhesive film is effectively sorbed by the moisture sorbent and thus does not reach the organic electronic device. Simultaneously, the moisture sorbent of the first adhesive layer in direct contact with the organic electronic device may function to stop problems such as separation of the encapsulant, cracking or film thinning, and to prevent physical/chemical damage to the organic electronic device due to the moisture sorbent, thus effectively improving properties of the adhesive film for an organic electronic device. If the ratio of Relation 1 exceeds 3.6, moisture that is not sorbed by the second adhesive layer but penetrates the first adhesive layer may not be efficiently sorbed by the first adhesive layer, making it difficult to obtain desired properties of the adhesive film. In contrast, if the ratio of Relation 1 is less than 1.0, moisture sorption efficiency by the second adhesive layer may be remarkably lowered. Furthermore, as a large amount of moisture may penetrate the first adhesive layer, the moisture sorbent of the first adhesive layer cannot completely sorb the moisture, or a large amount of moisture sorbent should be added to the first adhesive layer, undesirably causing problems, such as direct physical/chemical damage to the organic electronic device due to the moisture sorbent, cracking of the first adhesive layer or loosening therefrom, separation of the organic electronic device and the first adhesive layer, and film thinning.

In a preferred embodiment of the present invention, the weight ratio of moisture sorbent of each layer may satisfy 1.8˜3.6 in Relation 1, yielding an adhesive film having more improved properties.

The adhesive film for an organic electronic device according to the present invention may be manufactured by the following method, which is merely illustrative but is not limited thereto.

Specifically, in Step (1), preparing a first adhesive layer composition for a first adhesive layer and a second adhesive layer composition for a second adhesive layer is performed.

The first adhesive layer composition may include a moisture sorbent containing hollow silica, a first adhesive component, a curing agent, a curing accelerant, and a solvent, and the second adhesive layer composition may include a moisture sorbent, a second adhesive component, a curing agent, a curing accelerant, and a solvent.

The specific kinds and amounts of moisture sorbent, first adhesive component, second adhesive component, curing agent and curing accelerant in the first and the second adhesive layer composition are described as above and thus the descriptions thereof are omitted.

The kind of solvent may vary depending on the kind of adhesive component, and is not particularly limited in the present invention. Non-limiting examples of the solvent include saturated aliphatic hydrocarbons (e.g. n-pentane, hexane, n-heptane, iso-octane and dodecane), cyclo-aliphatic hydrocarbons (e.g. cyclopentane and cyclohexane), aromatic hydrocarbons (e.g. benzene, toluene, xylene and mesitylene), cyclic ether (e.g. tetrahydrofuran (THF) and dioxane), ketone (e.g. methyl isobutyl ketone (MIBK), methyl ethyl ketone (MEK)), halogenated alkane (e.g. trichloroethane) and halogenated aromatic hydrocarbons (e.g. bromobenzene and chlorobenzene), which may be used alone or in combination of two or more. The solvent has to have a volatilization temperature of 100° C. or less because workability or durability of the adhesive film may become problematic due to excessively long drying time or drying at high temperature. Also, a solvent having a volatilization temperature higher than 100° C. may be mixed in a small amount, depending on the type of film forming component. The amount of the solvent may vary depending on the adhesive layer composition, and is not particularly limited in the present invention.

When the components as above are mixed in the solvent, a ball mill, a bead mill, a 3-roll, or a high-speed grinder may be used to increase dispersibility of the moisture sorbent. The material for ball or bead is not particularly limited, but may include glass, alumina, or zirconium. Preferably useful is ball or bead made of zirconium in terms of dispersibility of particles.

In Step (2), applying the prepared first adhesive layer composition or second adhesive layer composition on a base film such as a release film is performed, thus forming a first adhesive layer or a second adhesive layer.

The base film such as a release film may be a release film known in the art, and the material therefor may include polyethylene terephthalate. Applying each adhesive layer composition on the release film may be implemented using any one process selected from among a variety of processes for applying an adhesive composition in the art, such as comma coating, reverse coating, gravure coating, blade coating, silk screen coating and slot die head coating. Specifically, the adhesive layer composition is applied on one side of the base film such as a release film using any one coating process as above, and then dried at 80˜150° C. for 1˜10 min. However, the present invention is not limited to such a formation process.

In Step (3), laminating the first adhesive layer and the second adhesive layer formed in Step (2) is performed, thus forming an adhesive film.

The first adhesive layer and the second adhesive layer may be combined to face each other and laminated using any known process in the art. Preferably, a lamination process at 50˜100° C. is carried out. As such, pressure may be further applied, provided that the extent of applied pressure is not particularly limited in the present invention.

In the manufacturing method as above, the first adhesive layer and the second adhesive layer are separately formed and then laminated. Alternatively, the adhesive film may be manufactured by forming a first adhesive layer on a base film such as a release film and then applying a second adhesive composition on the first adhesive layer, thus forming a second adhesive layer. The specific method or sequence for manufacturing the adhesive film is not particularly limited in the present invention.

Meanwhile, the present invention addresses an encapsulant for an organic electronic device, including the adhesive film as above, and also a light emitting device including the encapsulant.

The light emitting device includes a substrate, an organic electronic device formed on at least one side of the substrate, and an encapsulant according to the present invention for packaging the organic electronic device.

FIG. 4 is a schematic cross-sectional view illustrating a light emitting device 100 according to a preferred embodiment of the present invention. The light emitting device 100 is configured such that an organic electronic device 102 is formed on at least one side of the substrate 101, and encapsulants 111, 112 are formed on the substrate 101 and the organic electronic device 102. The encapsulants include a first adhesive layer 111 comprising a moisture sorbent 111a containing hollow silica and a first adhesive component 111b, and a second adhesive layer 112 comprising a moisture sorbent 112a and a second adhesive component 112b.

The substrate 101 may be any one selected from among a glass substrate, a quartz substrate, a sapphire substrate, a plastic substrate and a flexible polymer film.

The organic electronic device 102, which is provided on at least one side of the substrate 101, may be formed in such a manner that a lower electrode thin film is disposed on the substrate 102 and then an n-type semiconductor layer, an active layer, a p-type semiconductor layer and an upper electrode are sequentially stacked thereon and then etched, or may be formed via a separate substrate and then disposed on the substrate 101 as above. Forming the organic electronic device 102 on the substrate 101 may be implemented using any process known in the art, and is not particularly limited in the present invention. As such, the organic electronic device 102 may be an organic light emitting diode.

Next, the encapsulants 111, 112 according to the present invention are provided to package the organic electronic device 102. The packaging may be conducted using any process known in the art, and is not particularly limited in the present invention. Specifically, to the organic electronic device 102 formed on the substrate 101, heat and/or pressure may be applied using a vacuum press or a vacuum laminator under the condition that the first adhesive layer 111 of the encapsulants 111, 112 is in direct contact with the organic electronic device 102. Furthermore, heat may be applied to cure the adhesive layer. For the adhesive including the adhesive component to be photocured, a curing process may be carried out in a chamber into which light is radiated.

A better understanding of the present invention may be obtained via the following examples which are set forth to illustrate, but are not to be construed as limiting the present invention.

### Example 1

A first adhesive layer was formed as follows. Specifically, 100 parts by weight of an epoxy resin comprising 50 wt % of high-purity (total Cl content: 500 ppm or less, n=0) silicone modified liquid epoxy (XFR-8628) in which a silicone intermediate having a phenyl group is substituted and 50 wt % of DCPD type solid epoxy (HP-7200L, DIC) was added with 100 parts by weight of a phenoxy resin (PKHH, Inchem), thus preparing a first adhesive component. Based on 100 parts by weight of the first adhesive component, 150 parts by weight of a methylethylketone solvent was added, and the resulting mixture was stirred at room temperature for 2 hr. The stirred mixture was added with 1.5 parts by weight of an acid anhydride curing agent (B4500, DIC) based on 100 parts by weight of the first adhesive component, and also, 25 parts by weight of hollow silica (HS300, Sukgyung) having a dispersion coefficient of 40% for a particle size as shown in Table 1 below dispersed using an ultrasonic processor was added as a moisture sorbent, and the resulting mixture was stirred at room temperature for 2 hr. Subsequently, 5 parts by weight of a curing accelerant (2PZCNS-PW, Shikoku Chemicals) was added and the resulting mixture was further stirred for 1 hr. The viscosity of the stirred mixture was adjusted to 400 cps at 20° C., after which the mixture was passed through a capsule filter to remove impurities, and then applied on an antistatic heavy release PET (RT81AS, SKCHass) film having a thickness of 75 μm using a slot die coater, and dried at 120° C. to remove the solvent, thus manufacturing a first adhesive layer having a final thickness of 7 μm.

Thereafter, a second adhesive layer was formed as follows. Specifically, 100 parts by weight of an epoxy resin comprising 50 wt % of a high-purity (total Cl content: 500 ppm or less, n=0) silicone modified liquid epoxy (XFR-8628) in which a silicone intermediate having a phenyl group is substituted and 50 wt % of a DCPD type solid epoxy (HP-7200L, DIC) was added with 100 parts by weight of a phenoxy resin (PKHH, Inchem), thus preparing a second adhesive component. Based on 100 parts by weight of the second adhesive component, 150 parts by weight of a methylethylketone solvent was added, and the resulting mixture was stirred at room temperature for 2 hr. The stirred mixture was added with 1.5 parts by weight of an acid anhydride curing agent (B4500, DIC) based on 100 parts by weight of the second adhesive component. Also, 22.8 parts by weight of calcium oxide (purity 98%, Daejung Chemicals & Metals) dispersed using a ball mill was added as a moisture sorbent, and the resulting mixture was stirred at room temperature for 2 hr, after which 5 parts by weight of a curing accelerant (2PZCNS-PW, Shikoku Chemicals) was added, and the resulting mixture was further stirred for 1 hr. The viscosity of the stirred mixture was adjusted to 800 cps at 20° C., after which the mixture was passed through a capsule filter to remove impurities, and then applied on a light release PET (RF02, SKCHass) film having a thickness of 38 μm using a slot die coater, and dried at 120° C. to remove the solvent, thus manufacturing a second adhesive layer having a final thickness of 23 μm.

The first adhesive layer and the second adhesive layer were combined to face each other and laminated through a roll laminator at 70° C., thereby manufacturing an adhesive film as shown in Table 1 below.

### Examples 2 to 8

Adhesive films as shown in Table 1 below were manufactured in the same manner as in Example 1, with the exception that the kind and the amount of the moisture sorbent of the first and the second adhesive layer were changed as shown in Table 1 below.

### Comparative Examples 1 to 5

Adhesive films as shown in Table 2 below were manufactured in the same manner as in Example 1, with the exception that the kind and the amount of the moisture sorbent of the first and the second adhesive layer were changed as shown in Table 2 below.

### Test Example 1

The adhesive films of the examples and comparative examples were measured for the following properties. The results are shown in Tables 1 and 2 below.

Evaluation of Moisture Penetration of Adhesive Film

A test sample was cut to a size of 95 mm×95 mm, and then attached so as to be positioned inwards by 2.5 mm from four edges of alkali-free glass having a size of 100 mm×100 mm from which a protective film had been removed, using a roll laminator at 65° C. The release film remaining on the attached test sample was removed, after which another 100 mm×100 mm sized alkali-free glass was covered thereon, followed by lamination at 65° C. for 1 min using a vacuum laminator, thereby manufacturing a test sample having no voids. The completed test sample was cured in a heating oven at 100° C. for 3 hr, and the moisture penetration length was observed using a microscope at a temporal interval of 100 hr in a reliable chamber set at 85° C. and a relative humidity of 85%.

2. Evaluation of Volume Expansion of Adhesive Film

A release film was removed from the test sample, and then the test sample was attached to a 30 mm×20 mm sized SUS plate having a thickness of 50 μm using a roll laminator heated to about 65° C. The attached test sample was cut with a blade so as to be adapted to the size of the SUS plate, and then attached to a 40 mm×30 mm 0.7 T sized alkali-free glass using a roll laminator heated to 65° C. Whether the test sample was well attached without voids between the glass and the SUS plate was checked, after which curing was performed in a heating oven at 100° C. for 3 hr. Then, the test sample was observed for 1000 hr at a temporal interval of 100 hr in a reliable chamber set at 85° C. and relative humidity of 85%. Specifically, changes in height of the test sample at a portion having sorbed moisture based on the SUS plate were observed using an optical microscope. The case where the change in height at a portion having sorbed moisture was less than 1 μm was evaluated to be ⊚, the case where such a height change was in the range of 1 to less than 3 μm was evaluated to be ◯, the case where such a height change was in the range of 3 to less than 5 μm was evaluated to be Δ, and the case where such a height change was 5 μm or more was evaluated to be x.

### Test Example 2

An organic light emitting device (hole transport layer NPD/thickness 800 Å light emitting layer Alq3/thickness 300 Δ electron injection layer LiF/thickness 10 Å cathode Al+Liq/thickness 1,000 Δ) was deposited on a substrate having an ITO pattern, after which the adhesive film of each of the examples and comparative examples was laminated on the manufactured device at room temperature, covered with upper glass, and cured in a heating oven at 100° C. for 3 hr, thereby manufacturing an OLED sample for emitting green. This sample was measured for the following properties. The results are shown in Tables 1 and 2 below.

1. Evaluation of Durability of Organic Light Emitting Device Due to Moisture Penetration of Adhesive Film

Pixel shrinkage and formation and/or growth of dark spots at the light emitting portion of the test sample over time under conditions of a temperature of 85° C. and a relative humidity of 85% were observed with an ×100 digital microscope at a temporal interval of 100 hr. Then, a period of time required to generate pixel shrinkage of 50% or more and/or to form dark spots was measured.

The case where the period of time required to generate pixel shrinkage of 50% or more and to form dark spots was 1000 hr or more was evaluated to be ⊚, the case where such a period of time was in the range of 800 hr to less than 1000 hr was evaluated to be ◯, the case where such a period of time was in the range of 600 hr to less than 800 hr was evaluated to be Δ, and the case where such a period of time was less than 600 hr was evaluated to be λ.

2. Evaluation of Durability of Adhesive Film

In order to evaluate physical damage, the test sample was observed with an optical microscope for 1000 hr at an interval of 100 hr in a reliable chamber set at 85° C. and a relative humidity of 85%, in terms of interfacial separation of the organic electronic device and the adhesive film, cracking or void generation in the adhesive film, and separation of adhesive layers. The case where there was no abnormality was evaluated to be ◯, and the case where there was abnormality such as interfacial separation, cracking or void generation in the adhesive film and separation of adhesive layers was evaluated to be x.

TABLE 1

| | | | Ex. 1 | Ex. 2 | Ex. 3 | Ex. 4 | Ex. 5 | Ex. 6 | Ex. 7 | Ex. 8 |
|---|---|---|---|---|---|---|---|---|---|---|
| Composition | 1^{st} | A + B amount¹⁾ | 25 | 25 | 25 | 7 | 25 | 25 | 25 | 25 |
| | adhesive | (wt part) | | | | | | | | |
| | layer | A amount²⁾ | 100 | 55 | 85 | 100 | 100 | 100 | 100 | 100 |
| | | (wt %) | | | | | | | | |
| | | B amount³⁾ | 0 | 45 | 15 | 0 | 0 | 0 | 0 | 0 |
| | | (wt %) | | | | | | | | |
| | | Average | 20 | 20 | 20 | 20 | 20 | 20 | 20 | 20 |
| | | diameter | | | | | | | | |
| | | (nm) of A | | | | | | | | |
| | | Average | 250 | 250 | 250 | 250 | 250 | 250 | 250 | 250 |
| | | diameter | | | | | | | | |
| | | (nm) of B | | | | | | | | |
| | 2^{nd} | B amount⁴⁾ | 22.8 | 22.8 | 22.8 | 22.8 | 25.8 | 28.9 | 6.1 | 9.1 |
| | adhesive | (wt part) | | | | | | | | |
| | layer | Average | 250 | 250 | 250 | 250 | 250 | 250 | 250 | 250 |
| | | diameter | | | | | | | | |
| | | (nm) of B | | | | | | | | |
| Adhesive | 1^{st} | Moisture | 25 | 25 | 25 | 8.5 | 22.7 | 20.8 | 55.6 | 45.5 |
| Film | adhesive | sorbent | | | | | | | | |
| | layer | (wt %) | | | | | | | | |
| | | Thick. (μm) | 7 | 7 | 7 | 7 | 7 | 7 | 7 | 7 |
| | 2^{nd} | Moisture | 75 | 75 | 75 | 91.5 | 77.3 | 79.2 | 44.4 | 54.5 |
| | adhesive | sorbent | | | | | | | | |
| | layer | (wt %) | | | | | | | | |
| | | Thick. (μm) | 23 | 23 | 23 | 23 | 23 | 23 | 23 | 23 |

| | | | | | | | | | |
|---|---|---|---|---|---|---|---|---|---|
| | Relation 1⁵⁾ | 3.0 | 3.0 | 3.0 | 10.7 | 3.4 | 3.8 | 0.8 | 1.2 |
| | Moisture penetration | 5.1 | 6.0 | 5.7 | 6.1 | 4.7 | 4.5 | 6.2 | 5.6 |
| | length (μm/hr) | | | | | | | | |
| | Volume expansion | ⊚ | ⊚ | ⊚ | ⊚ | ◯ | Δ | ⊚ | ⊚ |
| OLED sample | Durability of organic | ⊚ | Δ | ◯ | Δ | ⊚ | ⊚ | Δ | ◯ |
| | light emitting device | | | | | | | | |
| | Durability of | ◯ | ◯ | ◯ | ◯ | ◯ | X | ◯ | ◯ |
| | adhesive film | | | | | | | | |

¹⁾A: hollow silica, B: calcium oxide, the amount is based on 100 wt parts of 1^{st} adhesive component
²⁾Amount of A of moisture sorbent in 1^{st} adhesive layer
³⁾Amount of B of moisture sorbent in 1^{st} adhesive layer
⁴⁾Amount of B (calcium oxide) of moisture sorbent in 2^{nd} adhesive layer
⁵⁾Relation 1 = moisture sorbent (g) of 2^{nd} adhesive layer ÷ moisture sorbent (g) of 1^{st} adhesive layer

TABLE 2

| | | | Ex. 9 | Ex. 10 | Ex. 11 | Ex. 12 | C. Ex. 1 | C. Ex. 2 | C. Ex. 3 |
|---|---|---|---|---|---|---|---|---|---|
| Composition | 1^{st} | A + B amount¹⁾ | 25 | 25 | 25 | 25 | 25 | 25 | 10 |
| | adhesive | (wt part) | | | | | | | |
| | layer | A amount²⁾ | 85 | 100 | 100 | 100 | 45 | 0 | 0 |
| | | (wt %) | | | | | | | |
| | | B amount³⁾ | 15 | 0 | 0 | 0 | 55 | 100 | 100 |
| | | (wt %) | | | | | | | |
| | | Average | 830 | 450 | 780 | 830 | 20 | 20 | 20 |
| | | diameter | | | | | | | |
| | | (nm) of A | | | | | | | |
| | | Average | 250 | 250 | 250 | 250 | 250 | 250 | 250 |
| | | diameter | | | | | | | |
| | | (nm) of B | | | | | | | |
| | 2^{nd} | B amount⁴⁾ | 22.8 | 22.8 | 22.8 | 22.8 | 22.8 | 22.8 | 25.2 |
| | adhesive | (wt part) | | | | | | | |
| | layer | Average | 750 | 250 | 250 | 250 | 250 | 250 | 250 |
| | | diameter | | | | | | | |
| | | (nm) of B | | | | | | | |
| Adhesive | 1^{st} | Moisture | 25 | 25 | 25 | 25 | 25 | 25 | 10.8 |
| Film | adhesive | sorbent | | | | | | | |
| | layer | (wt %) | | | | | | | |
| | | Thick. (μm) | 7 | 7 | 7 | 7 | 7 | 7 | 7 |
| | 2^{nd} | Moisture | 75 | 75 | 75 | 75 | 75 | 75 | 89.2 |
| | adhesive | sorbent | | | | | | | |
| | layer | (wt %) | | | | | | | |
| | | Thick. (μm) | 23 | 23 | 23 | 23 | 23 | 23 | 23 |

| | | | | | | | | |
|---|---|---|---|---|---|---|---|---|
| | Relation 1⁵⁾ | 3.0 | 3.0 | 3.0 | 3.0 | 3.0 | 3.0 | 6.9 |
| | Moisture penetration | 5.6 | 5.2 | 5.1 | 5.2 | 5.0 | 4.5 | 6.2 |
| | length (μm/hr) | | | | | | | |
| | Volume expansion | ⊚ | ⊚ | ⊚ | ⊚ | X | X | X |
| OLED sample | Durability of organic | Δ | ⊚ | ◯ | Δ | Δ | X | X |
| | light emitting device | | | | | | | |
| | Durability of | X | ◯ | ◯ | X | X | X | X |
| | adhesive film | | | | | | | |

¹⁾A: hollow silica, B: calcium oxide, the amount is based on 100 wt parts of 1^{st} adhesive component
²⁾Amount of A of moisture sorbent in 1^{st} adhesive layer
³⁾Amount of B of moisture sorbent in 1^{st} adhesive layer
⁴⁾Amount of B (calcium oxide) of moisture sorbent in 2^{nd} adhesive layer
⁵⁾Relation 1 = moisture sorbent (g) of 2^{nd} adhesive layer ÷ moisture sorbent (g) of 1^{st} adhesive layer

As is apparent from Tables 1 and 2, in Comparative Example 1 where the amount of hollow silica of the moisture sorbent in the first adhesive layer was 45 wt %, moisture removal was more efficient and thus the moisture penetration length was shorter than in Examples 1 to 3, but volume expansion of the adhesive film was significant, and thus poor durability of the adhesive film resulted due to cracking or interfacial separation of the adhesive film in the OLED sample.

In Comparative Example 2 where the moisture sorbent of the first adhesive layer contained no hollow silica, the moisture penetration length was shorter than in Comparative Example 1, but the volume expansion of the adhesive film was significant and thus durability of the adhesive film remarkably deteriorated due to cracking, interfacial separation and void generation of the adhesive film in the OLED sample.

In Examples 1 to 3, as the amount of the hollow silica of the moisture sorbent in the first adhesive layer was higher, the moisture penetration length was shorter and various properties became superior.

In Example 4, when the amount of the moisture sorbent of the first adhesive layer was much lower than that of the moisture sorbent of the second adhesive layer, moisture removal was not efficient, and the moisture penetration length was significantly increased, and thus durability of the organic light emitting device became poor.

Also, in Examples 1, 5 and 6 where the ratio of the amount of moisture sorbent of the second adhesive layer relative to the amount of moisture sorbent of the first adhesive layer, as represented in Relation 1, was increased from 3.0 to 3.4 and 3.8, as the amount of the moisture sorbent of the second adhesive layer was higher than the amount of the moisture sorbent of the first adhesive layer, the moisture penetration length was reduced but the extent of volume expansion of the adhesive film increased. Particularly in Example 6, durability of the adhesive film became poor.

In Examples 1, 8 and 7 where the ratio of the amount of moisture sorbent of the second adhesive layer relative to the amount of moisture sorbent of the first adhesive layer, as represented in Relation 1, was lowered from 3.0 to 1.2 and 0.8, as the amount of the moisture sorbent of the second adhesive layer was lower than the amount of the moisture sorbent of the first adhesive layer, moisture removal was not efficient and thus the moisture penetration length was considerably increased compared to Example 1. In Example 7, moisture removal was not efficient and thus durability of the organic light emitting device of the OLED sample was significantly deteriorated.

Compared to Examples 3 and 1, in Examples 9 and 12 where the average diameter of the hollow silica in the first adhesive layer was greater than 800 nm, durability of the organic light emitting device and durability of the adhesive film were remarkably decreased.

Also, as the average diameter of the hollow silica in the first adhesive layer was closer to 800 nm, durability of the organic light emitting device became slightly poor, as confirmed in Examples 1, 10 and 11.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An adhesive film for an organic electronic device, comprising:
a first adhesive layer including a moisture sorbent and a first adhesive component; and
a second adhesive layer formed on the first adhesive layer and including a moisture sorbent and a second adhesive component,
wherein the moisture sorbent of the first adhesive layer includes 50 wt % or more of hollow silica.

2. The adhesive film of claim 1, wherein the first adhesive component and the second adhesive component include any one or more functional groups selected from among thermocurable or photocurable glycidyl, isocyanate, hydroxyl, carboxyl, alkenyl, alkynyl and acrylate groups.

3. The adhesive film of claim 1, wherein the moisture sorbent of the first adhesive layer is used in an amount of 10˜50 parts by weight based on the first adhesive component.

4. The adhesive film of claim 1, wherein the moisture sorbent of the first adhesive layer and the second adhesive layer satisfies Relation 1 below:
$$1.0 \leq \frac{\begin{matrix}weight ( g ) of moisture \\ sorbent of 2 nd adhesive layer\end{matrix}}{ \begin{matrix}weight ( g ) of moisture \\ sorbent of 1 st adhesive layer\end{matrix}} \leq 3.6 . \qquad [ Relation 1 ]$$

5. The adhesive film of claim 1, wherein the hollow silica has a spherical shape and has an average particle size of 10˜800 nm.

6. The adhesive film of claim 1, wherein the moisture sorbent of the first adhesive layer includes 80 wt % or more of hollow silica.

7. The adhesive film of claim 4, wherein the moisture sorbent of the first adhesive layer and the second adhesive layer satisfies Relation 1 below:
$$1.8 \leq \frac{\begin{matrix}weight ( g ) of moisture \\ sorbent of 2 nd adhesive layer\end{matrix}}{\begin{matrix}weight ( g ) of moisture \\ sorbent of 1 st adhesive layer\end{matrix}} \leq 3.6 . \qquad [ Relation 1 ]$$

8. The adhesive film of claim 1, wherein the second adhesive layer is provided in a form of a monolayer or a multilayer.

9. The adhesive film of claim 1, wherein the moisture sorbent of the second adhesive layer is used in an amount of 20˜100 parts by weight based on 100 parts by weight of the second adhesive component.

10. The adhesive film of claim 1, wherein the first adhesive layer or the second adhesive layer has a thickness at least two times an average particle size of the moisture sorbent of each layer.

11. An encapsulant for an organic electronic device, comprising the adhesive film of claim 1.

12. A light emitting device, comprising:
a substrate;
an organic electronic device formed on at least one side of the substrate; and
the encapsulant of claim 11 for packaging the organic electronic device.
